(19) United States
(12) Patent Application Publication
(10) Pub. No.: US 2025/0137133 A1
(43) Pub. Date: May 1, 2025

(54) METHODS AND APPARATUS FOR SUSCEPTOR LEVELING

(71) Applicant: ASM IP Holding B.V., Almere (NL)

(72) Inventor: Hannelore Azora Hemminger, Tempe, AZ (US)

(21) Appl. No.: 18/928,355

(22) Filed: Oct. 28, 2024

Related U.S. Application Data
(60) Provisional application No. 63/546,626, filed on Oct. 31, 2023.

(51) Int. Cl. C23C 16/458; H01L 21/687

(52) U.S. Cl. CPC C23C 16/4584; H01L 21/68764

(57) ABSTRACT

Various embodiments of the present technology may provide a susceptor with adjustment mechanisms coupled to the shaft of the susceptor. A flexible rotary shaft may be coupled to the adjustment mechanism, and a motor may be connected to the flexible rotary shaft to rotate the adjustment mechanism. The adjustment mechanism may be one that moves susceptor in a horizontal direction or one that moves the susceptor in a vertical direction.

### CROSS-REFERENCE TO RELATED APPLICATIONS

This application is a nonprovisional of, and claims priority to and the benefit of, U.S. Provisional Patent Application No. 63/546,626, filed Oct. 31, 2023 and entitled “METHODS AND APPARATUS FOR SUSCEPTOR LEVELING,” which is hereby incorporated by reference herein.

### FIELD OF INVENTION

The present disclosure generally relates to a method and apparatus for susceptor leveling. More particularly, the present disclosure relates to susceptor leveling by remote devices.

### BACKGROUND OF THE TECHNOLOGY

Susceptor heaters used in semiconductor manufacturing may need periodic leveling. Conventional methods for leveling are done manually (i.e., by hand), which involves a tedious process of adjusting each leveler one by one and taking measurements after each adjustment. In addition, the space in which the levelers are located are tight and crowded making them difficult to access.

### SUMMARY OF THE INVENTION

Various embodiments of the present technology may provide a susceptor with adjustment mechanisms coupled to the shaft of the susceptor. A flexible rotary shaft may be coupled to the adjustment mechanism, and a motor may be connected to the flexible rotary shaft to rotate the adjustment mechanism. The adjustment mechanism may be one that moves susceptor in a horizontal direction or one that moves the susceptor in a vertical direction.

According to one aspect, an apparatus comprises: a susceptor comprising: a body comprising a first surface and a second opposing surface; and a pedestal coupled to the second surface of the body; a leveling assembly coupled to the pedestal, and comprising: a first plurality of adjustment mechanisms configured to move the pedestal in a vertical direction; and a second plurality of adjustment mechanisms configured to move the pedestal along a horizontal plane; an adjustment assembly comprising: a first plurality of flexible shafts, each one of the first plurality of flexible shafts coupled to one adjustment mechanism from the first plurality of adjustment mechanisms; a second plurality of flexible shafts, each one of the second plurality of flexible shafts coupled to one adjustment mechanism from the second plurality of adjustment mechanisms; a first plurality of motors, each motor coupled to one shaft from the first plurality of flexible shafts; and a second plurality of motors, each motor coupled to one shaft from the second plurality of shafts; and a controller communicatively coupled to each motor from the first and second plurality of motors.

In one embodiment, the apparatus further comprises a rotary encoder coupled to each adjustment mechanism from the first plurality of adjustment mechanisms and configured to detect a degree of rotation of the respective adjustment mechanism and generate an encoder signal.

In one embodiment, the controller is communicatively coupled to the rotary encoder and configured to receive the encoder signal.

In one embodiment, each motor from the first and second plurality of motors comprises a servo motor.

In one embodiment, the controller is configured to transmit a first control signal to at least motor from the first plurality of motors, and wherein the controller is configured to operate each motor from the first plurality of motors independently from the other motors.

In one embodiment, the controller is configured to transmit a second control signal to at least one motor from the second plurality of motors, and wherein the controller is configured to operate each motor from the second plurality of motors independently from the other motors.

In one embodiment, each adjustment mechanism from the first plurality of adjustment mechanisms comprises a rotating body.

In another aspect, a system comprises: a susceptor comprising: a body comprising a first surface and a second opposing surface; and a pedestal coupled to the second surface of the body; a leveling assembly coupled to the pedestal, and comprising: a first plurality of adjustment mechanisms configured to move the pedestal in a vertical direction; a sensing system configured to measure a direction of tilt of the susceptor body and generate a sensor signal indicating the direction of tilt; an adjustment assembly coupled to the leveling assembly and configured to individually rotate the adjustment mechanisms from the first plurality of adjustment mechanisms; and a controller coupled to the sensing system and the adjustment assembly, wherein the controller is configured to receive the sensor signal, generate an adjustment signal according to the sensor signal, and transmit the adjustment signal to the adjustment assembly.

In one embodiment, the adjustment assembly comprises: a first plurality of flexible shafts, each one of the first plurality of flexible shafts coupled to one adjustment mechanism from the first plurality of adjustment mechanisms; and a first plurality of motors, each motor coupled to one shaft from the first plurality of flexible shafts.

In one embodiment, the leveling assembly further comprises a second plurality of adjustment mechanisms configured to move the pedestal along a horizontal plane.

In one embodiment, the adjustment assembly further comprises: a second plurality of flexible shafts, each one of the second plurality of flexible shafts coupled to one adjustment mechanism from the second plurality of adjustment mechanisms; and a second plurality of motors, each motor coupled to one shaft from the second plurality of shafts.

In one embodiment, the controller is communicatively coupled to each motor from the first plurality of motors and configured to transmit the adjustment signal to at least one motor from the first plurality of motors.

In one embodiment, each adjustment mechanism from the first plurality of adjustment mechanisms comprises a rotating body.

In one embodiment, the system further comprises a rotary encoder coupled to each adjustment mechanism from the first plurality of adjustment mechanisms and configured to detect a degree of rotation of the respective adjustment mechanism.

In one embodiment, each motor from the first plurality of motors comprises a servo motor.

In yet another aspect, a system comprises: a susceptor comprising: a body comprising a first surface and a second opposing surface; and a pedestal coupled to the second surface of the body; a leveling assembly coupled to the pedestal, and comprising: a first plurality of adjustment mechanisms configured to move the pedestal in a vertical direction; a sensing system configured to measure a direction of tilt of the susceptor body and generate a sensor signal indicating the measured direction of tilt; an adjustment assembly coupled to the leveling assembly and configured to individually rotate the adjustment mechanisms from the first plurality of adjustment mechanisms, wherein the adjustment assembly comprises: a first plurality of flexible shafts, each one of the first plurality of flexible shafts coupled to one adjustment mechanism from the first plurality of adjustment mechanisms; and a first plurality of motors, each motor coupled to one shaft from the first plurality of flexible shafts; and a controller coupled to the sensing system and the adjustment assembly, wherein the controller is configured to: receive the sensor signal; generate an adjustment signal according to the sensor signal; and transmit the adjustment signal to at least one motor from the first plurality of motors.

In one embodiment, the adjustment assembly further comprises: a second plurality of flexible shafts, each one of the second plurality of flexible shafts coupled to one adjustment mechanism from the second plurality of adjustment mechanisms; and a second plurality of motors, each motor coupled to one shaft from the second plurality of shafts.

In one embodiment, the system further comprises a rotary encoder coupled to each adjustment mechanism from the first plurality of adjustment mechanisms and configured to detect a degree of rotation of the respective adjustment mechanism.

In one embodiment, each motor from the first plurality of motors comprises a servo motor.

In one embodiment, the first plurality of adjustment mechanisms are configured to move the pedestal in a vertical direction.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 representatively illustrates a system in accordance with embodiments of the present technology;

FIG. 3 representatively illustrates a substrate mounting unit with a leveling assembly in accordance with embodiments of the present technology;

FIG. 4 representatively illustrates the leveling assembly in accordance with embodiments of the present technology;

FIG. 5A representatively illustrates a cross sectional view of a portion of the leveling assembly in accordance with embodiments of the present technology;

FIG. 5B representatively illustrates a cross sectional view of a portion of the leveling assembly in accordance with embodiments of the present technology;

FIG. 6 representatively illustrates an exploded view of the leveling assembly in accordance with embodiments of the present technology;

FIG. 7 representatively illustrates an adjustment mechanism in accordance with embodiments of the present technology;

FIG. 8 representatively illustrates a portion of an adjustment mechanism in accordance with embodiments of the present technology; and

FIG. 9 is a flow chart for operating the system in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, power supply, pressure controllers, and filters.

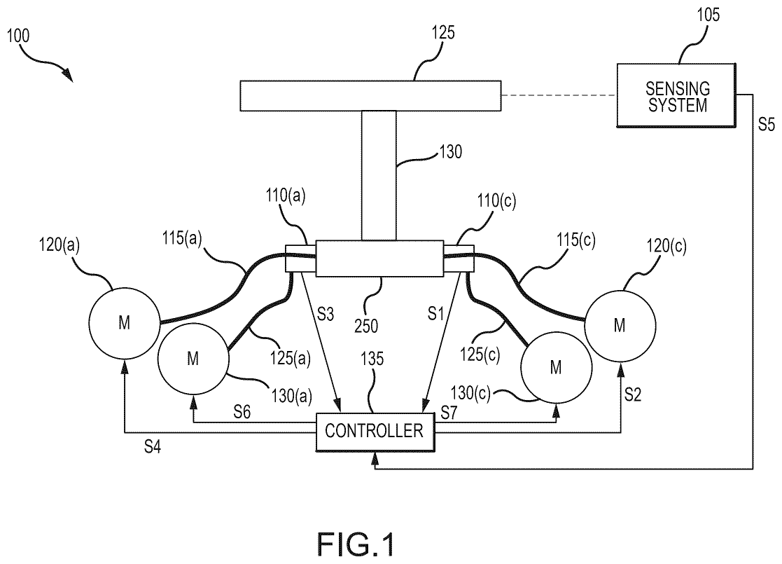

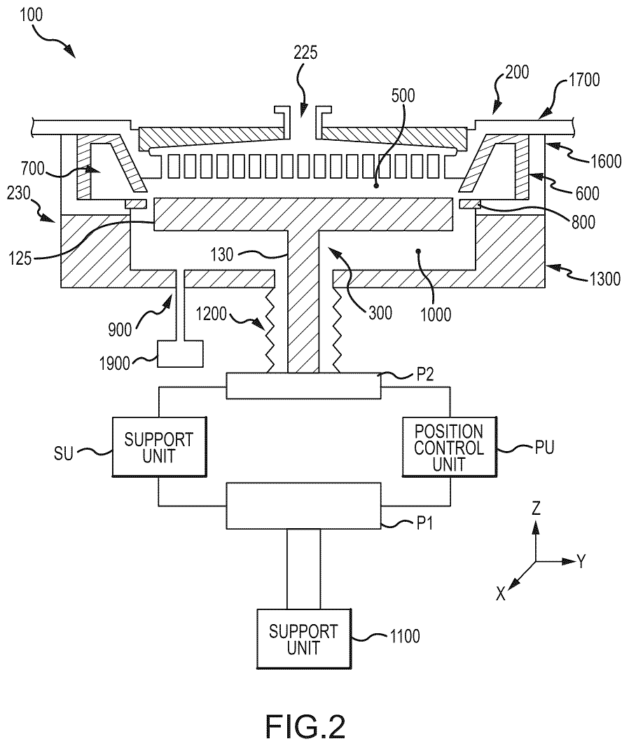

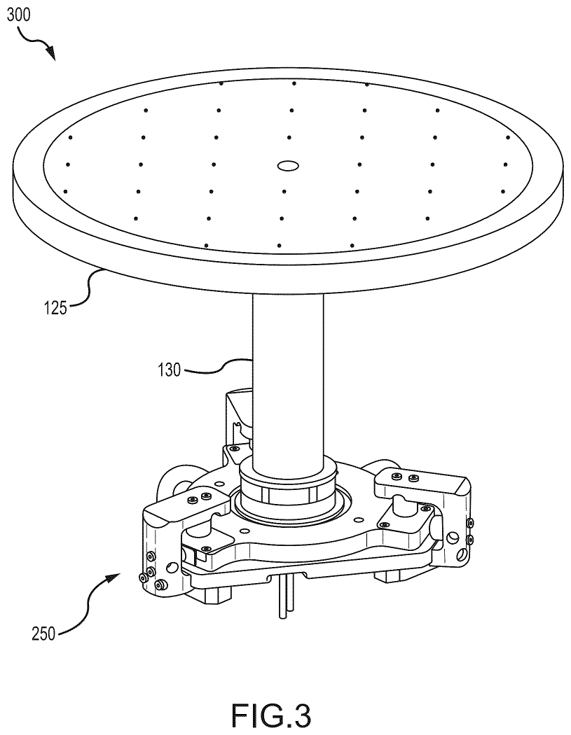

Referring to FIGS. 1 and 2, an exemplary system 100 may comprise a reactor 230 comprising an upper body 1600 and a lower body 1300. The upper body 1600 and the lower body 1300 may be connected to each other. In more detail, the upper body 1600 and the lower body 1300 of a reactor may form inner spaces 500 and 1000 while face-contacting and face-sealing each other. The reactor 230 may include, in the inner spaces 500 and 1000, a substrate mounting unit 300 (also referred to as a susceptor), and a ring 800 surrounding the substrate mounting unit 300 and arranged between the substrate mounting unit 300 and the upper body 1600.

The reactor 230 may be configured to perform processing on an object to be processed, such as a substrate (e.g., a wafer). For example, the reactor 230 may be configured to perform heating, deposition, etching, polishing, ion implantation, and/or other processing on the object to be processed. In some embodiments, the reactor 230 may be configured to perform a movement function, a vacuum sealing function, a heating function, an exhaust function, and/or other functions for the object to be processed such that the object is processed in the reactor. In an optional embodiment, the reactor 230 may be a reactor in which an atomic layer deposition (ALD) or a chemical vapor deposition (CVD) process is performed.

The upper body 1600 of the reactor may include a first gas inlet 225, a gas supply unit 200, an exhaust unit 600, and the ring 800. The lower body 1300 of the reactor may include a second gas inlet 900. The upper body 1600 and the substrate mounting unit 300 may form the reaction space 500. The lower body 1300 and the substrate mounting unit 300 may form the lower space 1000. A second gas generator 1900 may generate a filling gas, and the filling gas may be transmitted to the lower space 1000 through the second gas inlet 900.

The ring 800 may surround the substrate mounting unit 300 and may be arranged between the substrate mounting unit 300 and the upper body 1600. The ring 800 may generally have a circular ring shape, but is not limited thereto. For example, when the substrate mounting unit 300 has a quadrangular shape, the ring 800 may have a quadrangular ring shape. The ring 800 may be fixed to the upper body 1600. Alternatively, the ring 800 may be movably installed on the upper body 1600.

The substrate mounting unit 300 may comprise a susceptor body 125 for supporting the substrate and a heater (not shown) for heating the substrate supported by the susceptor body 125. The heater may be embedded within the susceptor body 125. The substrate mounting unit 300 may further comprise a pedestal 130 to support the susceptor body 125. For loading/unloading of the substrate, the substrate mounting unit 300 may be configured to be vertically movable by being connected to a driving unit 1100.

In various embodiments, the system 100 may further comprise a leveling assembly 250 coupled to the substrate mounting unit 300. For example, the leveling assembly 250 may be coupled directly to the pedestal 130. The leveling assembly 250 may include a first plate P1 and a second plate P2. The second plate P2 may be on the first plate P1, and the first plate P1 and the second plate P2 may be connected to each other through a support unit SU.

In various embodiments, the leveling assembly 250 may comprise a plurality of support units, such as a first support unit SU_V1, a second support unit SU_V2, a third support unit SU_V3, and a fourth support unit SU_H1.

The first plate P1 may be connected to the driving unit 1100. The first plate P1, the second plate P2, and the substrate mounting unit 300 may move by the driving of the driving unit 1100. In more detail, a driving force generated by the driving unit 1100 may be transmitted to the first plate P1, and the transmitted driving force may be transmitted from the first plate P1 to the second plate P2 through the support unit SU. As a result, the substrate mounting unit 300 connected to the second plate P2 may also be moved in a vertical direction (i.e., along the z-axis) by the driving of the driving unit 1100.

In various embodiments, the leveling assembly 250 may further comprise a position control unit PU. The position control unit PU may be configured to change a relative position of the second plate P2 with respect to the first plate P1 to maintain a constant interval of the reaction space 500 or to maintain a constant interval of the gap between the substrate mounting unit 300 and the ring 800.

The position control unit PU may comprise a plurality of horizontal position control units, such as a first horizontal adjustment mechanism PU_H1, a second horizontal adjustment mechanism PU_H3, and a third horizontal adjustment mechanism PU_H3, configured to move the second plate P2 in horizontal direction (along a horizontal plane).

The position control unit PU may further comprise a plurality of vertical position control units, such as a first vertical adjustment mechanism PU_V1, a second vertical adjustment mechanism PU_V2, and a third vertical adjustment mechanism PU_V3, configured to move the second plate P2 in a vertical direction to tilt the substrate mounting unit 300.

The driving unit 1100 may be configured to elevate the substrate mounting unit 300 to load/unload the substrate onto the substrate mounting unit 300. However, the position control unit PU may be configured to tilt the substrate mounting unit 300 for fine adjustment of the position of the substrate mounting unit 300. In addition, the driving unit 1100 may simultaneously move the first plate P1 and the second plate P2, while the position control unit PU may move only the second plate P2 without moving the first plate P1.

The driving unit 1100 and the position control unit PU may have movement ranges of different scales. The driving unit 1100 may have a movement range of, for example, several tens of cm, while the position control unit PU may have a movement range of several millimeters. In other words, a first movement range of the substrate mounting unit 300 moved by the driving unit 1100 may be greater than a second movement range of the substrate mounting unit 300 moved by the position control unit PU.

Each support unit SU may be configured to support the second plate P2. In more detail, a static support function and a dynamic support function for the support unit SU may be performed. First, with respect to the static support function, the support unit SU may be configured to provide a fixing force for fixing the second plate P2 so that the substrate mounting unit 300 may be maintained at a certain intended position. In other words, the support unit SU may perform a function of supporting the second plate P2 so that the second plate P2 may maintain a static state.

With respect to the dynamic support function, when the second plate P2 is moved by the position control unit PU, the support unit SU may allow the second plate P2 to move. The support unit SU may provide a support force for the second plate P2 while allowing the movement of the second plate P2. In other words, the support unit SU may support the second plate P2 with respect to relative movement of the second plate P2 with respect to the first plate P1, and the support unit SU may support the second plate P2 in a dynamic state of the second plate P2.

The support unit SU may be configured to transmit a fixing force of the first plate P1 with respect to the second plate P2 connected to the substrate mounting unit 300. In other words, the support unit SU may connect the first plate P1 to the second plate P2 such that a driving force generated by the driving unit 1100 may be transmitted from the first plate P1 to the second plate P2. A bolt or the like may be used for such a connection mechanism, but it should be noted that the transfer of a fixing force by the bolt or the like makes the second plate P2 over-constrained (i.e., a state that does not allow the movement of the second plate P2), thereby limiting relative movement between the first plate P1 and the second plate P2.

On the other hand, according to embodiments, the support unit SU may prevent the second plate P2 from being over-constrained by the position control unit PU. As described above, when the driving unit 1100 and the substrate mounting unit 300 are mechanically fixed using a bolt or the like, fine adjustment of the substrate mounting unit 300 is impossible due to an over-constrained state. On the other hand, because the support unit SU according to embodiments is configured to prevent such an over-constrained state, fine adjustment of the substrate mounting unit 300 may be achieved.

A stretchable portion 1200 may be between a lower surface of the lower body 1300 and the second plate P2. The stretchable portion 1200 may be arranged between the lower surface of the lower body 1300 and the second plate P2 to isolate the lower space 1000 from the outside.

The stretchable portion 1200 may be stretched and contracted according to movement of the substrate mounting unit 300 and the second plate P2. For example, the stretchable portion 1200 may have a corrugated configuration (e.g., a bellows). When the first plate P1, the second plate P2, and the substrate mounting unit 300 are raised by the driving unit 1100, the stretchable portion 1200 may contract. When the first plate P1, the second plate P2, and the substrate mounting unit 300 are descended by the driving unit 1100, the stretchable portion 1200 may expand.

In an optional embodiment, the stretchable portion 1200 may be configured to have elasticity. For example, the elasticity of the stretchable portion 1200 may be adjusted to be stretched or contracted in response to vertical movement of the substrate mounting unit 300 so that shielding between the lower surface of the lower body 1300 and the second plate P2 may be maintained. Due to the shielding of the stretchable portion 1200, the reaction space 500 and the lower space 1000 may be separated from a chamber space 1800.

A process gas introduced through the first gas inlet 100 may be supplied to the reaction space 500 and the substrate through the gas supply unit 200. The gas supply unit 200 may be a showerhead, and a base of the showerhead may include a plurality of gas supply holes formed to eject the process gas (e.g., in a vertical direction). A process gas supplied on the substrate may undergo a chemical reaction with the substrate or a chemical reaction between gases, and then deposit a thin film or etch a thin film on the substrate.

In the reaction space 500, a residual gas or un-reacted gas remaining after the chemical reaction with the substrate may be exhausted to the outside through an exhaust space 700 in an exhaust duct 600 and an exhaust pump (not shown). An exhaust method may be upper exhaust or lower exhaust.

It may be desirable to keep constant the distance between a lower surface of the gas supply unit 200 and an upper surface of the substrate on the substrate mounting unit 300. In other words, a distance between the substrate mounting unit 300 and the gas supply unit 200 at one end of the substrate mounting unit 300 needs to be equal to a distance between the substrate mounting unit 300 and the gas supply unit 200 at the other end of the substrate mounting unit 300.

Tilting and/or spacing adjustment performed during the process may be performed while the substrate is unloaded, for example, during an idle state. For example, during the idle state in the process, fine calibration of the substrate mounting unit 300 may be performed automatically. For example, by remotely controlling the position control unit PU during the idle state or during substrate processing, fine calibration of the substrate mounting unit 300 may be performed without an operator entering the chamber space 1800.

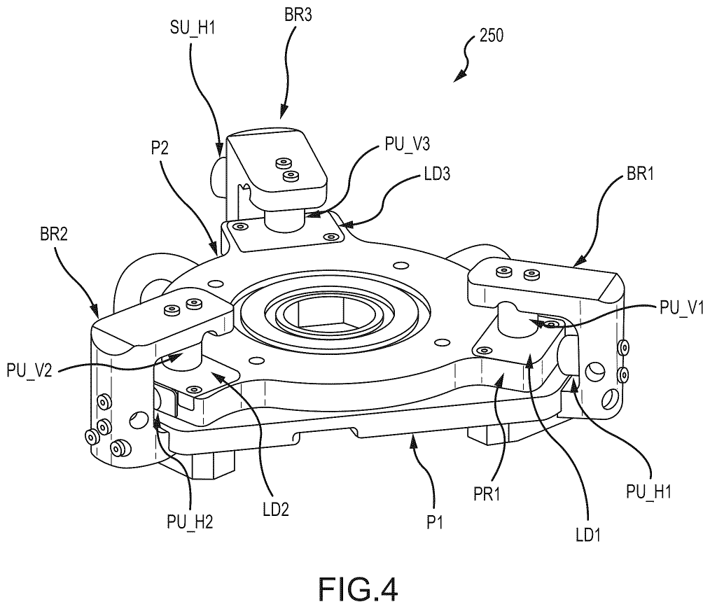

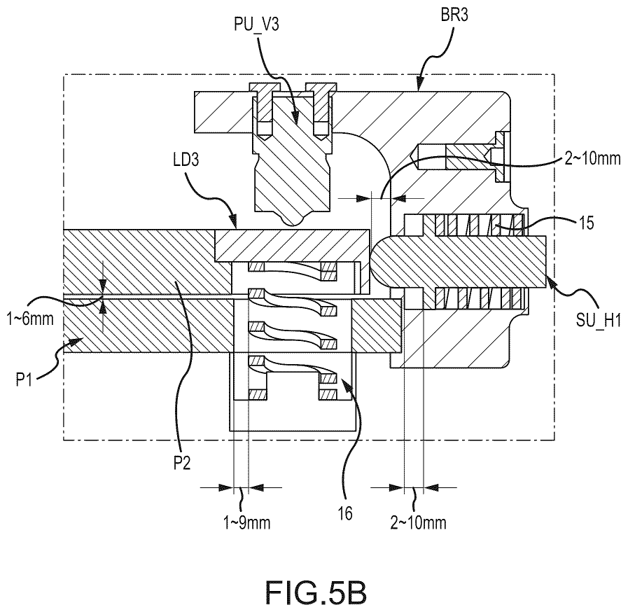

In various embodiments, and referring to FIGS. 4 and 6, the second plate P2 may comprise a first protrusion PR1, a second protrusion PR2, and a third protrusion PR3, which may be symmetrically arranged to have an angular distance of 120 degrees from each other.

In various embodiments, the leveling assembly 25 may further comprise first bracket BR1 connected to the first plate P1. The first bracket BR1 may be configured separately from the first plate P1 or may be integrally formed with the first plate P1. In an exemplary embodiment, the first horizontal adjustment mechanism PU_H1 may be fixed to the first bracket BR1. The first horizontal adjustment mechanism PU_H1 fixed to the first plate P1 through the first bracket BR1 may apply a force toward one side surface of the second plate P2, and by the force, the second plate P2 may move in the horizontal direction. In an exemplary embodiment, the first support unit SU_V1 may be fixed to the first plate P1 and may support the second plate P2 in the horizontal direction while allowing movement of the second plate P2 by the force generated by the horizontal position control unit PU_H1.

In addition, the leveling assembly 250 may further comprise a second bracket BR2 connected to the first plate P1. The second bracket BR2 may be configured separately from the first plate P1 or may be integrally formed with the first plate P1. In an exemplary embodiment, the second support unit SU_V2 may be fixed to the first plate P1 and may support the second plate P2 in the horizontal direction while allowing movement of the second plate P2 by the force generated by the horizontal position control unit PU_H2.

Similarly, the leveling assembly 250 may further comprise a third bracket BR3 connected to the first plate P1. The second bracket BR2 may be configured separately from the first plate P1 or may be integrally formed with the first plate P1. In an exemplary embodiment, the third support unit SU_V3 may be fixed to the first plate P1 and may support the second plate P2 in the horizontal direction while allowing movement of the second plate P2. The fourth support unit SU_H1 next to the third protrusion PR3 may contact a side surface of the third lid LD3 on the third protrusion PR3 to form a sixth contact point. Accordingly, the fourth support unit SU_H1 between the third bracket BR and a side surface of the third protrusion PR3 may change the position of the third protrusion PR3 of the second plate P2 through the sixth contact point.

In more detail, the fourth support unit SU_H1 may change the position of the third protrusion PR3 by passively moving in response to active movement of the fourth position control unit PU_H1 and the fifth position control unit PU_H2.

The support units SU may be on a bottom side surface of the second plate P2. In some embodiments, the position control units PU and the support units SU may be symmetrically arranged with respect to the center of the second plate P2. Accordingly, each support unit SU may generate a support force (e.g., an elastic force) corresponding to a force applied toward a side surface of the second plate P2 generated by the respective horizontal position control unit PU.

Brackets BR1, BR2, and BR3 and lower covers LC1, LC2, and LC3 may be installed to be fixed to the first plate P1 at positions where the first protrusion PR1, the second protrusion PR2, and the third protrusion PR3 are arranged. Lids LD1, LD2, and LD3 may be installed to be fixed to the second plate P2 at positions where the first protrusion PR1, the second protrusion PR2, and the third protrusion PR3 are arranged.

The lids LD1, LD2, and LD3 may be configured to be arranged on upper surfaces of the protrusions respectively to provide points of contact with a position control unit and/or a support unit. In an optional embodiment, the lids may be implemented to be integrated with the protrusion. In another embodiment, the lids may be implemented as a separate configuration and installed to be fixed to the second plate P2 (e.g., as shown in FIG. 6).

In more detail, the first vertical adjustment mechanism PU_V1 at the first protrusion PR1 may contact an upper surface of the first lid LD1 on the first protrusion PR1 to form a first contact point. Accordingly, the first vertical adjustment mechanism PU_V1 between the first bracket BR1 and an upper surface of the first protrusion PR1 may change the position of the first protrusion PR1 of the second plate P2 through the first contact point.

The second vertical adjustment mechanism PU_V2 on the second protrusion PR2 may contact an upper surface of the second lid LD2 on the second protrusion PR2 to form a second contact point. Accordingly, the second position control unit PU_V2 between the second bracket BR2 and an upper surface of the second protrusion PR2 may change the position of the second protrusion PR2 of the second plate P2 through the second contact point.

The third vertical adjustment mechanism PU_V3 on the third protrusion PR3 may contact an upper surface of the third lid LD3 on the third protrusion PR3 to form a third contact point. Accordingly, the third vertical adjustment mechanism PU_V3 between the third bracket BR and an upper surface of the third protrusion PR3 may change the position of the third protrusion PR3 of the second plate P2 through the third contact point.

In addition, the first horizontal adjustment mechanism PU_H1 next to the first protrusion PR1 may contact a side surface of the first lid LD1 on the first protrusion PR1 to form a fourth contact point. Accordingly, the first horizontal adjustment mechanism PU_H1 between the first bracket BR1 and a side surface of the first protrusion PR1 may change the position of the first protrusion PR1 of the second plate P2 through the fourth contact point.

The second horizontal adjustment mechanism PU_H2 next to the second protrusion PR2 may contact a side surface of the second lid LD2 on the second protrusion PR2 to form a fifth contact point. Accordingly, the second horizontal adjustment mechanism PU_H2 between the second bracket BR2 and a side surface of the second protrusion PR2 may change the position of the second protrusion PR2 of the second plate P2 through the fifth contact point.

The fourth support unit SU_H1 next to the third protrusion PR3 may contact a side surface of the third lid LD3 on the third protrusion PR3 to form a sixth contact point. Accordingly, the fourth support unit SU_H1 between the third bracket BR and a side surface of the third protrusion PR3 may change the position of the third protrusion PR3 of the second plate P2 through the sixth contact point.

In more detail, the fourth support unit SU_H1 may change the position of the third protrusion PR3 by passively moving in response to active movement of the first horizontal adjustment mechanism PU_H1 and the second horizontal adjustment mechanism PU_H2.

In addition, the first support unit SU_V1 below the first vertical adjustment mechanism PU_V1 may penetrate the first plate P1 and the second plate P2 to contact the first lid LD1 to form a seventh contact point. Accordingly, the first support unit SU_V1 between the first lower cover LC1 and the first lid LD1 may change the position of the first protrusion PR1 of the second plate P2 through the seventh contact point.

In the same manner, the second support unit SU_V2 below the second vertical adjustment mechanism PU_V2 may penetrate the first plate P1 and the second plate P2 and contact the second lid LD2 to change the position of the second protrusion PR2 of the second plate P2, and the third support unit SU_V3 below the third vertical adjustment mechanism PU_V3 penetrates the first plate P1 and the second plate P2 and contacts the third lid LD3 to change the position of the third protrusion PR3 of the second plate P2.

In various embodiments, two horizontal position control units (i.e., the first horizontal adjustment mechanism PU_H1 and the second horizontal adjustment mechanism PU_H2) and one support unit (i.e., the fourth support unit SU_H1) may be symmetrically arranged with respect to the center of the second plate P2. In more detail, as shown in FIG. 6, they may be arranged to have an interval of 120 degrees from each other.

In various embodiments, the first plate P1 is fixed to the pedestal 130 of the susceptor 300 and cannot move, whereas the second plate P2 is movable in the horizontal direction by the plurality of horizontal adjustment mechanisms and tilting of the second plate P2 about a moving axis is also possible.

Tilting adjustment of susceptor 300 is made by movement of the vertical adjustment mechanisms PU_V1, PU_V2, PU_V3 installed in the vertical direction on the three brackets BR1, BR2, BR3. In more detail, when the vertical adjustment mechanisms PU_V1, PU_V2, PU_V3 move in the forward direction (+), the vertical adjustment mechanisms PU_V1, PU_V2, PU_V3 push an upper surface of the support units SU_V1, SU_V2, SU_V3 in the vertical direction, and the support units SU_V1, SU_V2, SU_V3 and the second plate P2 are moved in the vertical direction. Any one of the vertical adjustment mechanisms may move individually or simultaneously. In an embodiment, by varying a movement distance of each vertical adjustment mechanism, tilting in the vertical direction may be more precisely controlled. In order to precisely control the movement in the vertical direction, that is, tilting, the support units SU_V1, SU_V2, SU_V3 may include an elastic body 16. For example, the elastic body 16 of the support units SU_V1, SU_V2, SU_V3 may be a spring, and over-constraint by the vertical adjustment mechanisms PU_V1, PU_V2, PU_V3 may be prevented by using an elastic force of the spring. In an embodiment, the spring may be an elastic body such as a coil spring or a plate spring, and each elastic force may be 5 kgf to 15 kgf (total 5 kgf to 15 kgf×3 EA=15 kgf to 45 kgf).

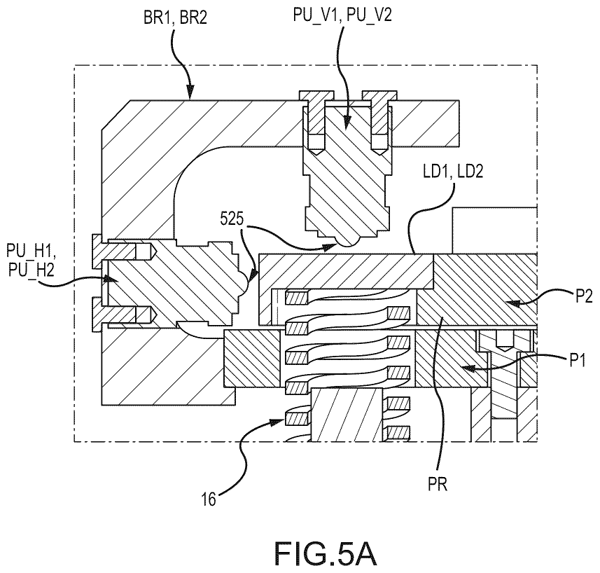

In various embodiments, and referring to FIGS. 5A-5B, when the horizontal adjustment mechanisms PU_H2, PU_H2 move in a horizontal direction, the support units SU_V1, SU_V2 and the second plate P2 are pushed in the horizontal direction, and the fourth support unit SU_H1 precisely controls the horizontal movement of the second plate P2 while controlling excessive movement or over-constraint of the second plate P2 that moves horizontally by an elastic force of a second elastic body 15.

The first elastic body 16 and the through-hole are apart from each other, and an end portion of the fourth support unit SU-H1 in contact with the third lid LD3 protrudes from an outer wall of the third bracket BR3 to facilitate horizontal movement of the second plate P3. For example, as shown in FIG. 5A, the second plate P2 may move horizontally by a separation distance between the elastic body 16 and the through-hole. In FIG. 5B, the separation distance is 1 mm to 9 mm, but is not limited thereto. In addition, because friction between the through-hole and the elastic body 16 may be prevented due to the gap, vertical movement and tilting of the second plate P2 may be made easier. There is a protrusion on the side of the fourth support unit SU_H1 so that coupling with the second elastic body 15 may be maintained.

On the other hand, when the vertical adjustment mechanisms PU_V1, PU_V2, PU_V3 move in a vertical direction, the support units SU_V1, SU_V2, SU_V3 and the second plate P2 are pushed in the vertical direction, and when the second plate P2 is tilted due to an elastic force of the first elastic body 16, the tilting of the second plate P2 is precisely controlled while controlling excessive movement or over-constraint. As shown, the second plate P2 is spaced apart from the first plate P1, so that the vertical movement or tilting of the second plate P2 may be made easier. In an exemplary embodiment, the separation distance is 1 mm to 6 mm, but is not limited thereto.

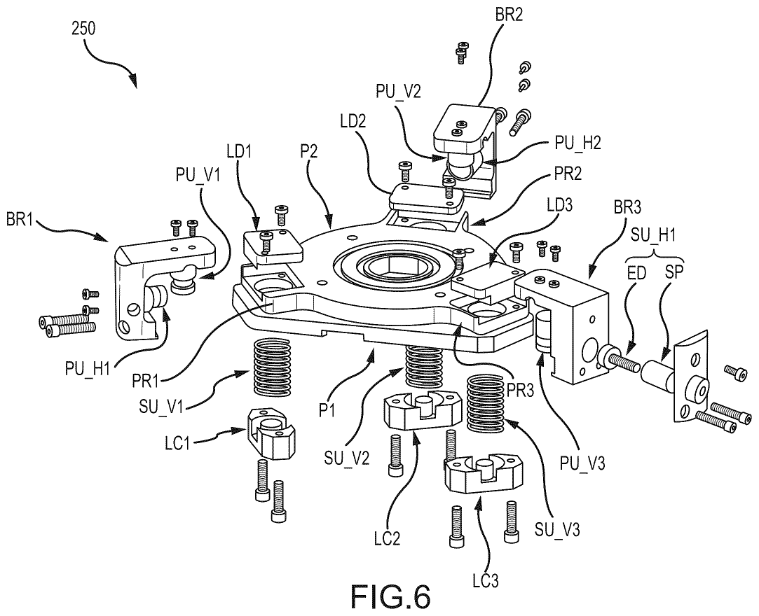

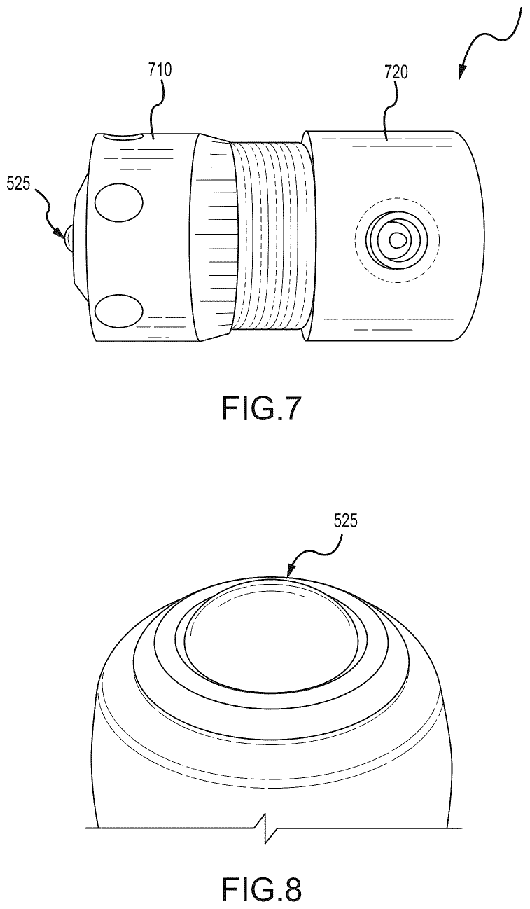

In various embodiments, and referring to FIGS. 7 and 8, the adjustment mechanisms PU_V1, PU_V2, PU_V3, PU_H1, PU_H2 may comprise a rotating body 710 and a fixed body 720. For example, the rotating body 710 may comprise a micrometer and may control horizontal movement or tilting of the second plate P2 according to a rotational displacement and its corresponding scale position of the rotating body 710 with respect to the fixed body 720. The fixed body 720 may be fixed to the bracket BR. The rotating body 710 may be rotatable about a central axis of the fixed body 720. The adjustment mechanism may further comprise a ball bearing 525 within the rotating body 710 and disposed at the central axis.

In various embodiments, and referring back to FIG. 1, the system may further comprise a controller 135 configured to receive and transmit various signals. The controller 135 may comprise any number of devices and systems suitable for receiving and transmitting a plurality of signals, performing decisions based on input signals, and the like. For example, the controller 135 may comprise a logic system and a memory.

In various embodiments, and referring back to FIG. 1, the system 100 may further comprise an adjustment assembly. The adjustment assembly may comprise a first plurality of flexible rotary shafts 115 (e.g., rotary shafts 115(a) and 115(b)) and a second plurality of flexible rotary shafts 125 (e.g., rotary shafts 125(a) and 125(b)). Each shaft 115, 125 may comprise a first end and a second end. Each shaft from the first plurality of flexible rotary shafts 115 may be coupled to a respective vertical adjustment mechanism PU_V at the first end. Similarly, each shaft from the second plurality of flexible rotary shafts 125 may be coupled to a respective horizontal adjustment mechanism PU_H at the first end.

In various embodiments, the flexible rotary shafts 115, 125 may be coupled to the respective adjustment mechanism (e.g., PU_V, PU_H) with any suitable fastener, such as a bracket, screw, or the like.

In various embodiments, the adjustment assembly may further comprise a first plurality of motors 120 (e.g., motors 120(a) and 120(c)) and a second plurality of motors 130 (e.g., motors 130(a) and 130(c)) configured to rotate a respective flexible rotary shaft. For example, each motor from the first plurality of motors 120 may be coupled to the second end of a respective shaft from the first plurality of flexible rotary shafts 115. Similarly, each motor from the second plurality of motors 130 may be coupled to the second end of a respective shaft from the second plurality of flexible rotary shafts 125. The motors 120, 130 may comprise any suitable motor, such as a servo motor, stepper motor, or the like.

In various embodiments, the motor may be configured to receive a control signal from the controller 135. The control signal may provide information to the motor 120 regarding a desired degree of rotation and the motor 120 may respond to the signal by moving the desired degree of rotation.

In various embodiments, and referring to FIGS. 1 and 7, the adjustment assembly may further comprise a plurality of rotary encoders 110 (e.g., rotary encoders 110(a) and 110(c)) configured to measure or otherwise detect a degree or amount of rotation of the moving body 710 of a respective adjustment mechanism from the first and second plurality of adjustment mechanisms PU_H, PU_V. For example, each adjustment mechanism PU_H, PU_V may be connected to a dedicated rotary encoder. The rotary encoder 110 may be coupled to the adjustment mechanism with any suitable fastener.

In various embodiments, the rotary encoder may transmit an encoder signal to the controller 135, wherein the encoder signal indicates an amount/degree of actual rotation of the moving body 710 of the adjustment mechanism.

In various embodiments, and referring to FIGS. 1 and 2, the system 100 may further comprise a sensing system 105 configured to detect a tilt of the susceptor 125 and/or to detect the horizontal placement of the susceptor 125 within the reaction chamber (i.e., centering). The sensing system 105 may comprise any suitable sensor to detect an amount or degree of tilt of the susceptor 125 and/or to detect the placement of the susceptor 125 within the reaction chamber relative to stationary elements, such as the sidewalls of the reaction chamber and/or the ring 800. For example, the sensing system 105 may detect or otherwise measure a horizontal gap between the outer edge of the susceptor 125 and the ring 800 and/or detect or otherwise measure a vertical gap between the top of susceptor 125 and the ring and/or some other stationary element. In some embodiments, the sensing system 105 may comprise a pyrometer, optical sensors, proximity sensors, laser sensors, flow sensors, temperature sensors, and the like.

In various embodiments, the sensing system 105 may be communicatively coupled to the controller 135. For example, the sensing system 105 may transmit an output sensor signal to the controller 135. The output sensor signal may indicate a numerical value and/or any other signal suitable for the type of sensor.

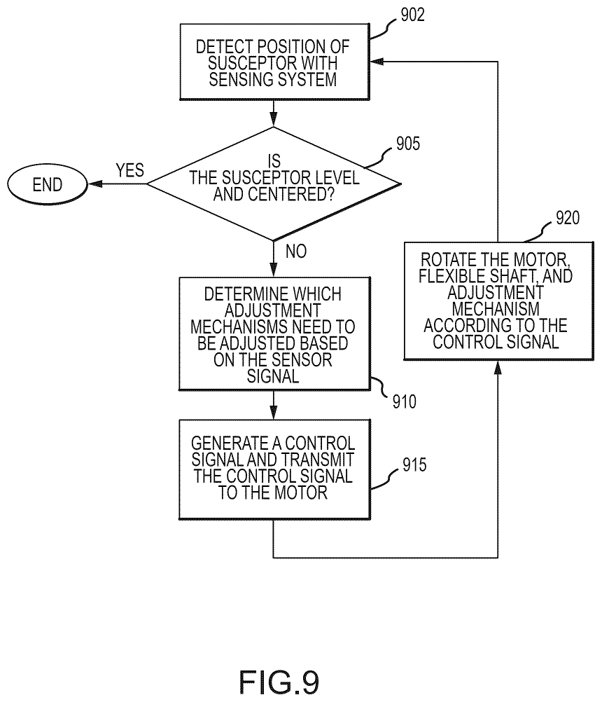

In operation, and referring to FIGS. 1, 6, 7, and 9, the system 100 may be configured to perform an automated, closed-loop method for leveling and/or centering the susceptor 125. This may be achieved by automatically operating the leveling assembly 250 and adjustment assembly. The sensing system 105 may first detect a position of the susceptor 125 (902). In an exemplary embodiment, the sensing system 105 may perform a measurement to determine if the susceptor 125 is tilted and/or off center. In some embodiments, an inert gas may be flowed through the showerhead 200 during sensor measurement. The sensing system 105 may generate an output sensor signal (e.g., signal S5) according to the measurement and transmit the output sensor signal to the controller 135. Based on the sensor measurement, the controller 135 may determine if the susceptor 125 is level and centered (905). If the susceptor 125 is level and centered, the leveling/centering process stops.

If the controller 135 determines that the susceptor 125 is not level, the controller 135 determines which adjustment mechanism needs to be adjusted to level/center the susceptor 125 based on the sensor signals (910). The controller 135 may then generate an output signal (e.g., signals S2, S4, S6, S7) and transmit the output signal to the motor 120(a) (915). The motor 120(a) then responds to the output signal S4 by rotating, and therefore, rotating the flexible rotary shaft 115(a). The flexible rotary shaft 115(a) may be coupled to the rotating body 710 of the first vertical adjustment mechanism PU_V1. Accordingly, when the motor 120 rotates, the flexible rotary shaft also rotates, thus rotating the rotating body 710, which moves the vertical adjustment mechanism up or down in the z-direction (920). This movement adjusts the tilt of the susceptor 125, as described above.

Similarly, the flexible rotary shaft may be coupled to the rotating body 710 of the first horizontal adjustment mechanism PU_H1. In this case, when the motor 120 rotates, the flexible rotary shaft also rotates, thus rotating the rotating body 710, which moves the horizontal adjustment mechanism along the x-y plane. This movement moves the susceptor 125 along the x-y plane, as described above.

In an exemplary embodiment, the controller 135 independently controls each motor 120 according to the output sensor signal. For example, the controller 135 may signal one motor 120 to rotate in one direction, while signaling a different motor 120 to rotate in another direction at the same time. Alternatively, the signaling from the controller 135 to the motors 120 may be in sequence.

As the susceptor moves according the adjustment mechanisms PU_H, PU_V, the sensor system 105 may continue to sense, detect, or otherwise measure the position of the susceptor 125 and continue to transmit output sensor signals to the controller 135. The leveling/centering process is complete when the controller determines that the susceptor 125 is level and centered.

In some embodiments, the controller 135 may utilize the encoder signal (e.g., signals S1, S3) from the rotary encoder 110 to confirm that the desired amount/degree of rotation of the motor 120 and rotary shaft 115, 125 is the same as the actual amount/degree of rotation of the moving body 710 of the adjustment mechanism PU_V/PU_H. For example, the controller 135 may receive the encoder signal, and if the actual rotation is not matching that of the desired rotation, the controller 135 may calibrate the next output control signal to account for any detected offset.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a susceptor comprising:
a body comprising a first surface and a second opposing surface; and
a pedestal coupled to the second surface of the body;
a leveling assembly coupled to the pedestal, and comprising:
a first plurality of adjustment mechanisms configured to move the pedestal in a vertical direction; and
a second plurality of adjustment mechanisms configured to move the pedestal along a horizontal plane;
an adjustment assembly comprising:
a first plurality of flexible shafts, each one of the first plurality of flexible shafts coupled to one adjustment mechanism from the first plurality of adjustment mechanisms;
a second plurality of flexible shafts, each one of the second plurality of flexible shafts coupled to one adjustment mechanism from the second plurality of adjustment mechanisms;
a first plurality of motors, each motor coupled to one shaft from the first plurality of flexible shafts; and
a second plurality of motors, each motor coupled to one shaft from the second plurality of shafts; and
a controller communicatively coupled to each motor from the first and second plurality of motors.

2. The apparatus according to claim 1, further comprising a rotary encoder coupled to each adjustment mechanism from the first plurality of adjustment mechanisms and configured to detect a degree of rotation of the respective adjustment mechanism and generate an encoder signal.

3. The apparatus according to claim 2, wherein the controller is communicatively coupled to the rotary encoder and configured to receive the encoder signal.

4. The apparatus according to claim 1, wherein each motor from the first and second plurality of motors comprises a servo motor.

5. The apparatus according to claim 1, wherein the controller is configured to transmit a first control signal to at least motor from the first plurality of motors, and wherein the controller is configured to operate each motor from the first plurality of motors independently from the other motors.

6. The apparatus according to claim 1, wherein the controller is configured to transmit a second control signal to at least one motor from the second plurality of motors, and wherein the controller is configured to operate each motor from the second plurality of motors independently from the other motors.

7. The apparatus according to claim 1, each adjustment mechanism from the first plurality of adjustment mechanisms comprises a rotating body.

8. A system, comprising:
a susceptor comprising:
a body comprising a first surface and a second opposing surface; and
a pedestal coupled to the second surface of the body;
a leveling assembly coupled to the pedestal, and comprising:
a first plurality of adjustment mechanisms configured to move the pedestal in a vertical direction;
a sensing system configured to measure a direction of tilt of the susceptor body and generate a sensor signal indicating the direction of tilt;
an adjustment assembly coupled to the leveling assembly and configured to individually rotate the adjustment mechanisms from the first plurality of adjustment mechanisms; and
a controller coupled to the sensing system and the adjustment assembly, wherein the controller is configured to receive the sensor signal, generate an adjustment signal according to the sensor signal, and transmit the adjustment signal to the adjustment assembly.

9. The system according to claim 8, wherein the adjustment assembly comprises:
a first plurality of flexible shafts, each one of the first plurality of flexible shafts coupled to one adjustment mechanism from the first plurality of adjustment mechanisms; and
a first plurality of motors, each motor coupled to one shaft from the first plurality of flexible shafts.

10. The system according to claim 8, wherein the leveling assembly further comprises a second plurality of adjustment mechanisms configured to move the pedestal along a horizontal plane.

11. The system according to claim 10, wherein the adjustment assembly further comprises:
a second plurality of flexible shafts, each one of the second plurality of flexible shafts coupled to one adjustment mechanism from the second plurality of adjustment mechanisms; and
a second plurality of motors, each motor coupled to one shaft from the second plurality of shafts.

12. The system according to claim 11, wherein the controller is communicatively coupled to each motor from the first plurality of motors and configured to transmit the adjustment signal to at least one motor from the first plurality of motors.

13. The system according to claim 8, wherein each adjustment mechanism from the first plurality of adjustment mechanisms comprises a rotating body.

14. The system according to claim 8, further comprising a rotary encoder coupled to each adjustment mechanism from the first plurality of adjustment mechanisms and configured to detect a degree of rotation of the respective adjustment mechanism.

15. The system according to claim 8, wherein each motor from the first plurality of motors comprises a servo motor.

16. A system, comprising:
a susceptor comprising:
a body comprising a first surface and a second opposing surface; and
a pedestal coupled to the second surface of the body;
a leveling assembly coupled to the pedestal, and comprising:
a first plurality of adjustment mechanisms configured to move the pedestal in a vertical direction;
a sensing system configured to measure a direction of tilt of the susceptor body and generate a sensor signal indicating the measured direction of tilt;
an adjustment assembly coupled to the leveling assembly and configured to individually rotate the adjustment mechanisms from the first plurality of adjustment mechanisms, wherein the adjustment assembly comprises:
a first plurality of flexible shafts, each one of the first plurality of flexible shafts coupled to one adjustment mechanism from the first plurality of adjustment mechanisms; and
a first plurality of motors, each motor coupled to one shaft from the first plurality of flexible shafts; and
a controller coupled to the sensing system and the adjustment assembly, wherein the controller is configured to:
receive the sensor signal;
generate an adjustment signal according to the sensor signal; and
transmit the adjustment signal to at least one motor from the first plurality of motors.

17. The system according to claim 16, wherein the adjustment assembly further comprises:
a second plurality of flexible shafts, each one of the second plurality of flexible shafts coupled to one adjustment mechanism from the second plurality of adjustment mechanisms; and
a second plurality of motors, each motor coupled to one shaft from the second plurality of shafts.

18. The system according to claim 16, further comprising a rotary encoder coupled to each adjustment mechanism from the first plurality of adjustment mechanisms and configured to detect a degree of rotation of the respective adjustment mechanism.

19. The system according to claim 16, wherein each motor from the first plurality of motors comprises a servo motor.

20. The system according to claim 16, wherein the first plurality of adjustment mechanisms are configured to move the pedestal in a vertical direction.
